(19) United States
(12) Patent Application Publication
(10) Pub. No.: US 2010/0207092 A1
(43) Pub. Date: Aug. 19, 2010

(54) PHASE CHANGE MEMORY DEVICE SWITCHED BY SCHOTTKY DIODES AND METHOD FOR MANUFACTURING THE SAME

(76) Inventor: Kang Sik Choi, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/421,767

(22) Filed: Apr. 10, 2009

(30) Foreign Application Priority Data
Feb. 16, 2009 (KR) 10-2009-0012582

(51) Int. Cl. H01L 45/00; H01L 21/329; H01L 21/20

(52) U.S. Cl. 257/3; 438/571; 438/478; 257/E45.002; 257/E21.09; 257/E21.359

(57) ABSTRACT

A phase change memory device and a method for manufacturing the same is presented. The phase change memory device includes a semiconductor substrate, a bit line, switching elements, bottom electrodes, a phase change layer, and top electrodes. The semiconductor substrate has a cell area and a peripheral area. The bit line is formed on the semiconductor substrate. The switching elements are formed on portions of the bit line in the cell area. The bottom electrodes are formed on the switching elements. The phase change layer is formed on the bottom electrodes. The top electrodes are formed on the phase change layer.

### CROSS-REFERENCE TO RELATED APPLICATIONS

The present application claims priority to Korean patent application number 10-2009-0012582 filed on Feb. 16, 2009, which is incorporated herein by reference in its entirety.

### BACKGROUND OF THE INVENTION

The present invention relates to a phase change memory device and a method for manufacturing the same, and more particularly, to a phase change memory device that can realize a reduced substrate resistance and thereby realize an improved current drivability.

Recently, research has been progressing in an effort to develop a novel memory device having a simple configuration and having a capacity of accomplishing a high level of integration while still being able to retain many of the desirable characteristics of a non-volatile memory device. One type of novel memory device, for example, is a phase change memory device.

In the phase change memory device, a reversible phase change occurs in a phase change layer interposed between a bottom electrode and a top electrode from a crystalline state to an amorphous state. This reversible phase change is brought about by driving a current between a pair of electrodes. Accordingly, information can be stored in a reversible phase change material cell by exploiting the difference in the resistance between the crystalline state and the amorphous state of the phase change layer material.

Meanwhile, one of the most important factors that must be considered to develop a phase change memory device is to reduce programming current. Recently, in order to reduce programming current, the cell switching elements of a phase change memory device have been configured by using diodes having high degree of current flow in place of NMOS transistors. Because a high degree of current flow can be maintained when using the diodes, it is possible to decrease the size of cells and therefore a high integration of a phase change memory device can be achieved.

PN diodes are generally used as diodes. Unfortunately in the conventional phase change memory devices in which PN diodes are exploited as switching elements, parasitic bipolar junction transistors necessarily occur between the PN diodes and a P-type substrate. Therefore, even though PN diodes provide a high degree of current flow, some of this driving current is lost through these parasitic bipolar junction transistors.

Conventional phase change memory devices that use PN diodes have a structure in which the plurality of PN diodes are electrically connected with one another through N+ regions formed in the surfaces of active regions. In this regard, resistance of the N+ regions are often times substantial and driving currents are likely to vary among the cells.

In addition, in the conventional phase change memory device that use PN diodes, complicated unit processes such as an epitaxial process should be conducted to form the PN diodes, and as a result the manufacturing procedure becomes involved.

Further, in the conventional phase change memory device having the PN diodes, in order to solve the problems caused due to the resistance of the N+ regions, a metal strapping method is adopted for every 8 bits. Consequently, in producing conventional phase change memory devices a large number of processes is required and the required area is large which results in deteriorating the economic efficiency of producing these devices.

### SUMMARY OF THE INVENTION

Embodiments of the present invention are directed to a phase change memory device which can prevent the loss of driving current due to the resistance of an N+ region and a method for manufacturing the same.

Also, embodiments of the present invention are directed to a phase change memory device which can prevent the variation of driving current among cells and a method for manufacturing the same.

Further, embodiments of the present invention are directed to a phase change memory device that can accomplish the simplification of processes and directed to a method for manufacturing the same.

In addition, embodiments of the present invention are directed to a phase change memory device that can prevent or at least minimize the number of fabrication processes and can reduce the required area. Thereby the present invention provides an improved economic efficiency, and a method for manufacturing the same.

In one aspect of the present invention, a phase change memory device preferably comprises a semiconductor substrate having a cell area and a peripheral area; a bit line formed on the semiconductor substrate; switching elements formed on portions of the bit line in the cell area; bottom electrodes formed on the switching elements; a phase change layer formed on the bottom electrodes; and top electrodes formed on the phase change layer.

The phase change memory device preferably further comprises a driving element formed in the peripheral area of the semiconductor substrate.

The switching elements are preferably Schottky diodes.

The Schottky diodes preferably have a stack structure of a metal layer and a P+ polysilicon layer.

The metal layer preferably has a work function of 3.5˜5.5 eV and contains at least one of, for example, Ag, Al, Au, Cr, Ni, Pt, Ti and W.

Both of the metal layer and the P+ polysilicon layer are preferably stacked in a dot type configuration.

The Schottky diodes preferably have a stack structure of a metal layer and an N+ polysilicon layer.

The metal layer preferably has a work function of 3.5˜5.5 eV and contains at least one of, for example, Ag, Al, Au, Cr, Ni, Pt, Ti and W.

Both of the metal layer and the N+ polysilicon layer are preferably stacked in a dot type configuration.

The phase change memory device preferably further comprises an ohmic contact layer formed on surfaces of the switching elements to be interposed between the switching elements and the bottom electrodes.

The ohmic contact layer preferably comprises a metal silicide.

The bottom electrodes preferably have a size that contacts only a limited portion of the phase change layer.

The phase change layer and the top electrodes preferably comprise line type stack patterns that extend in a direction substantially perpendicular to the bit line.

In another aspect of the present invention, a phase change memory device preferably comprises a semiconductor substrate having a cell area and a peripheral area; an interlayer dielectric formed on the semiconductor substrate; a bit line formed on the interlayer dielectric; a first insulation layer formed on the interlayer dielectric including the bit line and having a plurality of first holes that expose portions of the bit line; Schottky diodes formed in the first holes as switching elements; a second insulation layer formed on the first insulation layer including the Schottky diodes and having a plurality of second holes that expose the respective Schottky diodes; bottom electrodes formed on sidewalls of the second holes; a third insulation layer formed to fill the second holes that have the bottom electrodes formed on the sidewalls thereof; and a phase change layer and top electrodes stacked on the bottom electrodes, the third insulation layer and the second insulation layer.

The phase change memory device preferably further comprises a driving element formed in the peripheral area of the semiconductor substrate.

The Schottky diodes, which are formed in the first holes, preferably have a stack structure of a metal layer and a P+ polysilicon layer.

The metal layer preferably has a work function of 3.5˜5.5 eV and contains at least one of, for example, Ag, Al, Au, Cr, Ni, Pt, Ti and W.

The P+ polysilicon layer is preferably formed to be recessed into the first holes.

The Schottky diodes, which are preferably formed in the first holes, preferably have a stack structure of a metal layer and an N+ polysilicon layer.

The metal layer preferably has a work function of 3.5˜5.5 eV and contains at least one of, for example, Ag, Al, Au, Cr, Ni, Pt, Ti and W.

The N+ polysilicon layer is preferably formed to be recessed into the first holes.

The phase change memory device preferably further comprises an ohmic contact layer interposed between the Schottky diodes and the bottom electrodes.

The ohmic contact layer preferably comprises a metal silicide.

The phase change layer and the top electrodes preferably comprise line type stack patterns that extend in a direction substantially perpendicular to the bit line.

In another aspect of the present invention, a phase change memory device preferably comprises a semiconductor substrate having a cell area and a peripheral area; a bit line formed on the semiconductor substrate; switching elements formed on portions of the bit line in the cell area; bottom electrodes formed on the switching elements; insulation layer spacers formed on both side ends of the bottom electrodes; a phase change layer formed on the bottom electrodes between the insulation layer spacers; and top electrodes formed on the phase change layer.

The phase change memory device further preferably comprises a driving element formed in the peripheral area of the semiconductor substrate.

The switching elements formed on the portions of the bit line in the cell area preferably comprise Schottky diodes.

Each Schottky diode preferably has a stack structure of a metal layer which is formed on an overall surface of the bit line and an N+ polysilicon layer which is formed in a dot type configuration on portions of the metal layer.

The metal layer may have any work function, however the metal layer preferably has a work function of 3.5˜5.5 eV and contains at least one of, for example, Ag, Al, Au, Cr, Ni, Pt, Ti and W.

Each Schottky diode may have any shape and structure, however each Schottky diode preferably has a stack structure of a metal layer which is formed on an overall surface of the bit line and a P+ polysilicon layer which is formed in a dot type on portions of the metal layer.

The metal layer may have any work function, however the metal preferably has a work function of 3.5˜5.5 eV and contains at least one of, for example, Ag, Al, Au, Cr, Ni, Pt, Ti and W.

The phase change memory device preferably further comprises an ohmic contact layer interposed between the switching elements and the bottom electrodes.

The ohmic contact layer preferably comprises a metal silicide.

The insulation layer spacers may be any type of insulation layer spacers. One preferable insulation layer spacer comprise a nitride layer.

The top electrodes preferably comprise line type patterns which extend in a direction substantially perpendicular to the bit line.

In another aspect of the present invention, a phase change memory device preferably comprises a semiconductor substrate having a cell area and a peripheral area; an interlayer dielectric formed on the semiconductor substrate; a bit line formed on the interlayer dielectric; a metal layer formed on an overall surface of the bit line; an insulation layer formed on the interlayer dielectric including the metal layer and having a plurality of holes which expose portions of the metal layer; a polysilicon layer formed on bottoms of the respective holes, constituting Schottky diodes as switching elements in cooperation with the portions of the metal layer which are exposed through the holes, and having any one conductivity type of a first conductivity type and a second conductivity type; bottom electrodes formed on the polysilicon layer in the holes; insulation layer spacers formed on sidewalls of the holes at both side ends of the bottom electrodes; a phase change layer formed on the bottom electrodes between the insulation layer spacers to completely fill the holes; and top electrodes formed on the insulation layer including the phase change layer.

The phase change memory device may further comprise a driving element formed in the peripheral area of the semiconductor substrate.

The Schottky diodes may have any known structure and shape. One preferred structure and shape is that the Schottky diodes have a stack structure of a metal layer and an N+ polysilicon layer.

The metal layer may have any work function, in which it is preferable that the work function is between 3.5˜5.5 eV and contains at least one of, for example, Ag, Al, Au, Cr, Ni, Pt, Ti and W.

The Schottky diodes preferably have a stack structure of a metal layer and a P+ polysilicon layer.

The metal layer preferably has a work function of 3.5˜5.5 eV and contains at least one of, for example, Ag, Al, Au, Cr, Ni, Pt, Ti and W.

The phase change memory device may preferably further comprise an ohmic contact layer interposed between the polysilicon layer and the bottom electrodes.

The ohmic contact layer preferably comprises a metal silicide.

The insulation layer spacers preferably comprise a nitride layer.

The top electrodes may preferably comprise line type patterns which extend in a direction substantially perpendicular to the bit line.

In another aspect of the present invention, a method for manufacturing a phase change memory device preferably comprises the steps of forming a bit line on a semiconductor substrate that has a cell area and a peripheral area; forming switching elements on portions of the bit line in the cell area; forming bottom electrodes on the switching elements; and forming stack patterns of a phase change layer and a top electrode on the bottom electrodes.

Before the step of forming the bit line, the method may further comprise the step of forming a driving element in the peripheral area of the semiconductor substrate.

The switching elements preferably comprise Schottky diodes.

The Schottky diodes are preferably formed as a stack structure of a metal layer and a P+ polysilicon layer.

The metal layer preferably has a work function of 3.5˜5.5 eV and contains at least one of, for example, Ag, Al, Au, Cr, Ni, Pt, Ti and W.

Both of the metal layer and the P+ polysilicon layer are preferably formed in a dot type configuration.

The Schottky diodes are preferably formed as a stack structure of a metal layer and an N+ polysilicon layer.

The metal layer preferably has a work function of 3.5˜5.5 eV and contains at least one of, for example, Ag, Al, Au, Cr, Ni, Pt, Ti and W.

Both of the metal layer and the N+ polysilicon layer are preferably formed in a dot type.

After the step of forming the switching elements and before the step of forming the bottom electrodes, the method further also comprise the step of forming an ohmic contact layer on surfaces of the switching elements.

The ohmic contact layer preferably comprises a metal silicide.

The bottom electrodes are preferably formed to have a size that contacts a portion of the phase change layer.

The stack patterns of the phase change layer and the top electrode are preferably formed in the type of lines which extend in a direction substantially perpendicular to the bit line.

In another aspect of the present invention, a method for manufacturing a phase change memory device preferably comprises the steps of forming an interlayer dielectric on a semiconductor substrate that has a cell area and a peripheral area; forming a bit line on the interlayer dielectric; forming a first insulation layer on the interlayer dielectric including the bit line, the first insulation layer having a plurality of first holes that expose portions of the bit line; forming Schottky diodes in the respective first holes as switching elements; forming a second insulation layer on the first insulation layer including the Schottky diodes, the second insulation layer having a plurality of second holes that expose the respective Schottky diodes; forming bottom electrodes on sidewalls of the second holes; forming a third insulation layer to completely fill the second holes that have the bottom electrodes formed on the sidewalls thereof; and forming stack patterns of a phase change layer and a top electrode on the bottom electrodes, the third insulation layer and the second insulation layer.

Before the step of forming the interlayer dielectric, the method may further comprise the step of forming a driving element in the peripheral area of the semiconductor substrate.

The step of forming the Schottky diodes may comprise the steps of forming a metal layer on bottoms of the first holes; and forming a P+ polysilicon layer on the metal layer in the first holes.

The metal layer preferably has a work function of 3.5˜5.5 eV and contains at least one of, for example, Ag, Al, Au, Cr, Ni, Pt, Ti and W.

After the step of forming the P+ polysilicon layer, the method may further comprises the steps of recessing the P+ polysilicon layer; and forming an ohmic contact layer on a surface of the recessed P+ polysilicon layer.

The ohmic contact layer preferably comprises a metal silicide.

The step of forming the Schottky diodes comprises the steps of forming a metal layer on bottoms of the first holes; and forming an N+ polysilicon layer on the metal layer in the first holes.

The metal layer preferably has a work function of 3.5˜5.5 eV and contains at least one of, for example, Ag, Al, Au, Cr, Ni, Pt, Ti and W.

After the step of forming the N+ polysilicon layer, the method may further comprises the steps of recessing the N+ polysilicon layer; and forming an ohmic contact layer on a surface of the recessed N+ polysilicon layer.

The ohmic contact layer preferably comprises a metal silicide.

The stack patterns of the phase change layer and the top electrode are preferably formed in the type of lines that extend in a direction substantially perpendicular to the bit line.

In still another aspect of the present invention, a method for manufacturing a phase change memory device preferably comprises the steps of forming a bit line on a semiconductor substrate which has a cell area and a peripheral area; forming switching elements on portions of the bit line in the cell area; forming bottom electrodes on the switching elements; forming insulation layer spacers on both side ends of the switching elements; forming a phase change layer on the bottom electrodes between the insulation layer spacers; and forming top electrodes on the phase change layer.

Before the step of forming the bit line, the method may further comprise the step of forming a driving element in the peripheral area of the semiconductor substrate.

The switching elements preferably comprise Schottky diodes.

The Schottky diodes preferably have a stack structure of a metal layer and an N+ polysilicon layer.

The metal layer is preferably formed on an overall surface of the bit line, and the N+ polysilicon layer is formed on portions of the metal layer in a dot type.

The metal layer preferably has a work function of 3.5˜5.5 eV and contains at least one of, for example, Ag, Al, Au, Cr, Ni, Pt, Ti and W.

The Schottky diodes preferably have a stack structure of a metal layer and a P+ polysilicon layer.

The metal layer is preferably formed on an overall surface of the bit line, and the P+ polysilicon layer is formed on portions of the metal layer in a dot type.

The metal layer preferably has a work function of 3.5˜5.5 eV and contains at least one of, for example, Ag, Al, Au, Cr, Ni, Pt, Ti and W.

After the step of forming the switching elements and before the step of forming the bottom electrodes, the method may further comprise the step of forming an ohmic contact layer on surfaces of the switching elements.

The ohmic contact layer preferably comprises a metal silicide.

The insulation layer spacers preferably comprise a nitride layer.

The top electrodes are preferably formed as line type patterns that extend in a direction substantially perpendicular to the bit line.

In a still further aspect of the present invention, a method for manufacturing a phase change memory device preferably comprises the steps of forming an interlayer dielectric on a semiconductor substrate which has a cell area and a peripheral area; forming a bit line on the interlayer dielectric; forming a metal layer on an overall surface of the bit line; forming an insulation layer on the interlayer dielectric including the metal layer, the insulation layer having a plurality of holes which expose portions of the metal layer; forming a polysilicon layer on bottoms of the respective holes, the polysilicon layer constituting Schottky diodes as switching elements in cooperation with the portions of the metal layer which are exposed through the holes and having any one conductivity type of a first conductivity type and a second conductivity type; forming bottom electrodes on the polysilicon layer in the holes; forming insulation layer spacers on sidewalls of the holes at both side ends of the bottom electrodes; forming a phase change layer on the bottom electrodes between the insulation layer spacers to completely fill the holes; and forming top electrodes on the insulation layer including the phase change layer.

Before the step of forming the interlayer dielectric, the method may further comprise the step of forming a driving element in the peripheral area of the semiconductor substrate.

The Schottky diodes preferably have a stack structure of a metal layer and an N+ polysilicon layer.

The metal layer preferably has a work function of 3.5˜5.5 eV and contains at least one of, for example, Ag, Al, Au, Cr, Ni, Pt, Ti and W.

The Schottky diodes preferably have a stack structure of a metal layer and a P+ polysilicon layer.

The metal layer preferably has a work function of 3.5˜5.5 eV and contains at least one of, for example, Ag, Al, Au, Cr, Ni, Pt, Ti and W.

After the step of forming the polysilicon layer and before the step of forming the bottom electrodes, the method may further comprise the step of forming an ohmic contact layer on a surface of the polysilicon layer.

The ohmic contact layer preferably comprises a metal silicide.

The insulation layer spacers preferably comprise a nitride layer.

The top electrodes are formed as line type patterns that extend in a direction perpendicular to the bit line.

### BRIEF DESCRIPTION OF THE DRAWINGS

FIG. 1 is a sectional view illustrating a phase change memory device in accordance with a first embodiment of the present invention.

FIGS. 2A through 2F are sectional views illustrating the processes of a method for manufacturing the phase change memory device in accordance with the first embodiment of the present invention.

FIG. 3 is a sectional view illustrating a phase change memory device in accordance with a second embodiment of the present invention.

FIGS. 4A through 4F are sectional views illustrating the processes of a method for manufacturing the phase change memory Is device in accordance with the second embodiment of the present invention.

### DESCRIPTION OF SPECIFIC EMBODIMENTS

Hereafter, specific embodiments of the present invention will be described in detail with reference to the accompanying drawings.

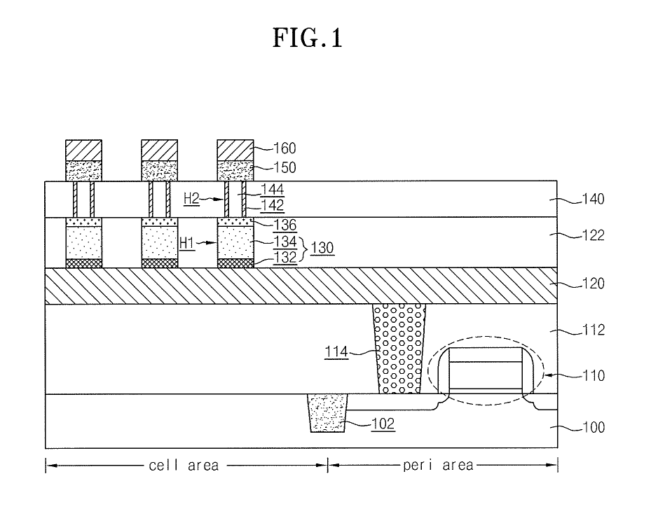

FIG. 1 is a sectional view illustrating a phase change memory device in accordance with a first embodiment of the present invention.

Referring to FIG. 1, a semiconductor substrate 100 is divided into a cell area and a peripheral area. An isolation structure 102 is formed in the surface of the semiconductor substrate 100 to delimit active regions in each of the cell area and the peripheral area. A driving element 110 such as a transistor including a gate and junction regions is formed in the peripheral area of the semiconductor substrate 100.

An interlayer dielectric 112 is formed on the overall surface of the semiconductor substrate 100 including the peripheral area which is formed with the driving element 110, and a bit line 120 is formed on the interlayer dielectric 112. The bit line 120 is preferably formed of a metal and is electrically connected with the driving element 110 that is formed in the peripheral area, through a plug 114. The plug 114 is formed of, for example, tungsten, and includes a barrier layer (not shown) that is formed on the interfaces of the plug 114 with the interlayer dielectric 112 and the driving element 110. Spacers (not shown) comprising a nitride layer are formed on both sidewalls of the bit line 120.

A first insulation layer 122 is formed on the interlayer dielectric 112 including the bit line 120. First holes H1 are defined in the first insulation layer 122 in correspondence to respective cells in such a way as to expose portions of the bit line 120, and Schottky diodes 130 serving as switching elements are formed in the respective first holes H1. Each Schottky diode 130 is composed of the stack of a metal layer 132 that is formed on the bottom of the first hole H1, that is, the portion of the bit line 120 exposed through the first hole H1, and a P+ polysilicon layer 134 which is formed on the metal layer 132 in the first hole H1. Both of the metal layer 132 and the P+ polysilicon layer 134 are stacked in a dot type. The metal layer 132 is formed of a metal which has a work function of 3.5˜5.5 eV. For example, the metal layer 132 is composed of a single layer formed of any one selected among Ag, Al, Au, Cr, Ni, Pt, Ti and W or an alloy layer containing at least one of them.

The P+ polysilicon layer 134 is formed to be recessed into the first hole H1. An ohmic contact layer 136 is formed on the recessed P+ polysilicon layer 134. Preferably, the ohmic contact layer 136 comprises a metal silicide.

Meanwhile, it is envisioned that the Schottky diode 130 can be formed by the stack structure of the metal layer 132 and an N+ polysilicon layer both of which are formed in a dot type, in place of the stack structure of the metal layer 132 and the P+ polysilicon layer 134 both of which are formed in a dot type. In the event that the Schottky diode 130 is a stack structure of the metal layer 132 and the N+ polysilicon layer, the N+ polysilicon layer is also formed to be recessed into the first hole H1, and similarly, the ohmic contact layer 136 comprising a metal silicide is formed on the recessed N+ polysilicon layer.

In succession, a second insulation layer 140 is formed on the Schottky diodes 130 including the ohmic contact layer 136 and on the first insulation layer 122. Second holes H2 are defined in the second insulation layer 140 in such a way as to expose the respective Schottky diodes 130, more precisely, the ohmic contact layer 136 on the respective Schottky diodes 130. Bottom electrodes 142 are formed in the form of spacers on the sidewalls of the second holes H2 in such a way as to be electrically connected with the Schottky diodes 130. A third insulation layer 144 is filled in the second holes H2 that have the bottom electrodes 142 formed on the sidewalls thereof.

The stack patterns of a phase change layer 150 and a top electrode 160 are formed on the second insulation layer 140 including the bottom electrodes 142 and the third insulation layer 144. Preferably, the stack patterns of the phase change layer 150 and the top electrode 160 are formed in the type of lines that extend in a direction substantially perpendicular to the bit line 120.

In the above-described phase change memory device in accordance with the first embodiment of the present invention, in the case that the Schottky diode 130 is composed of the stack structure of the metal layer 132 and the P+ polysilicon layer 134, current flows from the top electrode 160 to the bit line 120. Conversely, in the case that the Schottky diode 130 is composed of the metal layer 132 and the N+ polysilicon layer, current flows from the bit line 120 to the top electrode 160.

The above-described phase change memory device in accordance with the first embodiment of the present invention has Schottky diodes as switching elements. In particular, the phase change memory device has a structure in which the Schottky diodes are placed on a bit line.

Accordingly, since the phase change memory device in accordance with the first embodiment of the present invention has a configuration in which driving current is transmitted to the Schottky diodes of respective cells through the bit line formed of a metallic material, it is possible to prevent or at least minimize a voltage drop phenomenon from occurring and current drivability from deteriorating due to a relatively high resistance. For instance, in the conventional phase change memory device adopting PN diodes, an N+ region has sheet resistance of 200 Ω/□, whereas, in the phase change memory device according to the present invention, which is configured by forming the Schottky diodes on the bit line, sheet resistance decreases to 70 Ω/□. That is to say, resistance is reduced by about one third.

Also, in the phase change memory device in accordance with the first embodiment of the present invention, because it is possible to prevent driving current from varying among cells, it is not necessary to form a strap metal used for avoiding the variation of driving current among cells. Whereby the problems caused in terms of a more conventional design and processes can be substantially solved and substantially avoided.

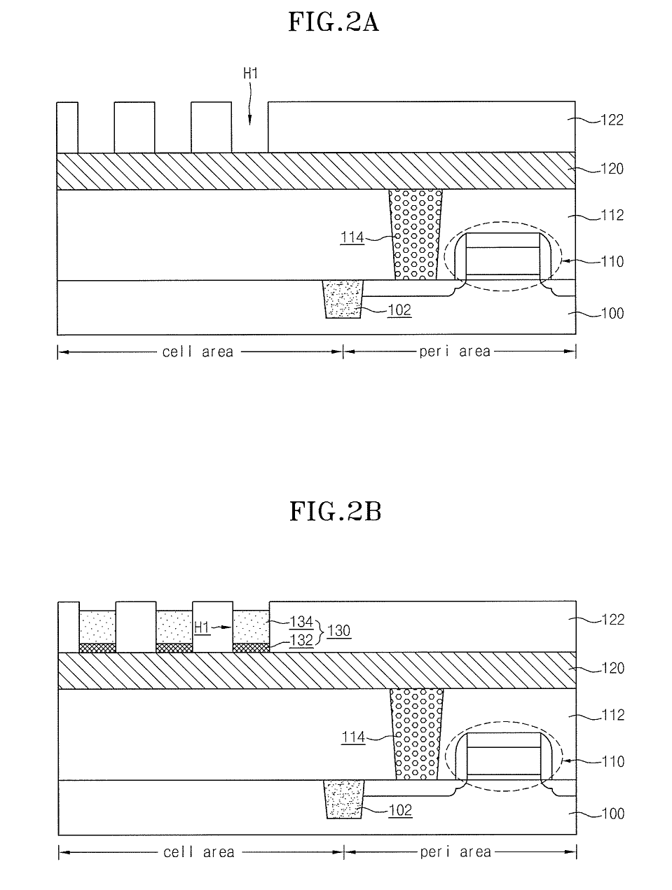

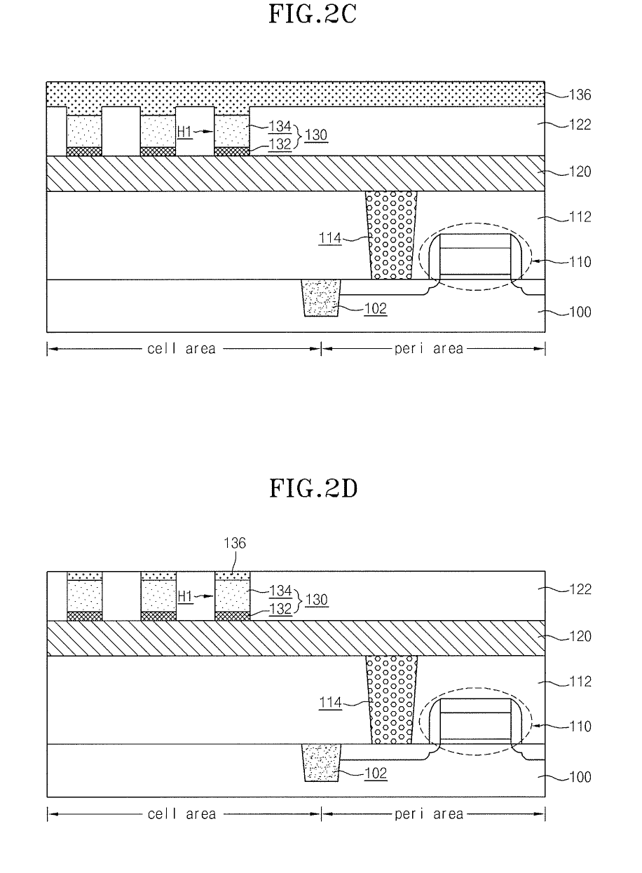

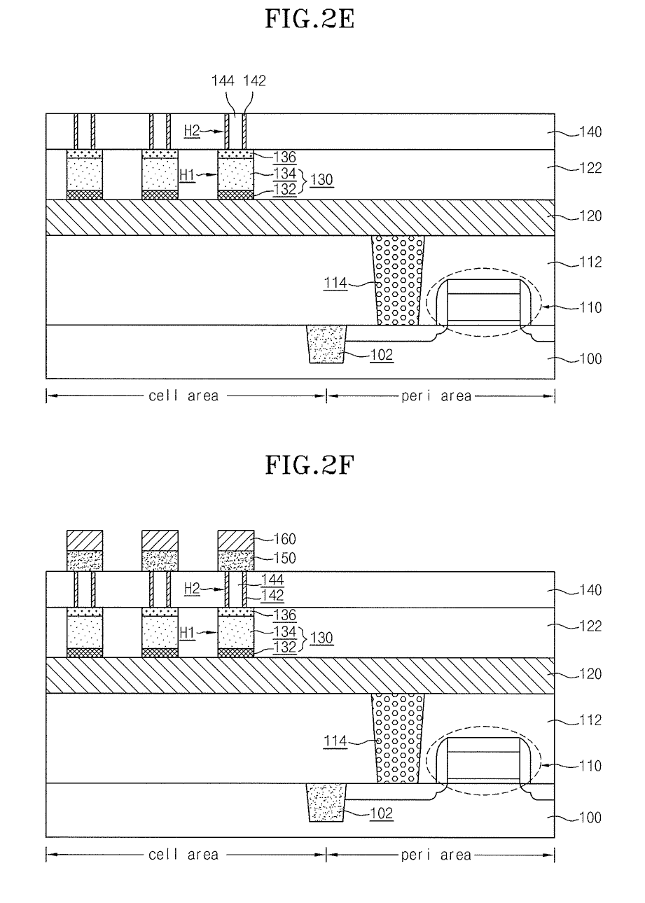

FIGS. 2A through 2F are sectional views illustrating the processes of a method for manufacturing the phase change memory device in accordance with the first embodiment of the present invention. The method will be described below.

Referring to FIG. 2A, an isolation structure 102 is formed in the surface of a semiconductor substrate 100 that has a cell area and a peripheral area, through an STI (shallow trench isolation) process in such a way as to delimit active regions in the cell area and the peripheral area. A driving element 110 such as a transistor including a gate and junction regions is formed in the active region of the peripheral area of the semiconductor substrate 100. An interlayer dielectric 112 is formed on the overall surface of the semiconductor substrate 100 including the peripheral area in which the driving element 110 is formed. After defining a contact hole by etching the interlayer dielectric 112 in such a way as to expose a portion of the driving element 110 that is formed in the peripheral areas a plug 114 is formed by filling a conductive layer, for example, a tungsten layer, in the contact hole. It is preferred that, before filling the tungsten layer, a barrier layer be formed in advance on the surface of the contact hole.

After depositing a metal layer for a bit line on the interlayer dielectric 112 including the plug 114, a hard mask (not shown) comprising a nitride layer is formed on the metal layer for a bit line, and then, a bit line 120 is formed by etching the metal layer for a bit line using the hard mask comprising a nitride layer as an etch mask. Next, spacers (not shown) comprising a nitride layer are formed on both sidewalls of the bit line 120.

After forming a first insulation layer 122 on the interlayer dielectric 112 including the bit line 120, by etching the insulation layer 122, a plurality of first holes H1 are defined in such a way as to expose portions of the bit line 120. The first holes H1 can be understood as being defined in correspondence to respective cells.

Referring now to FIG. 2B, after depositing a metal layer 132 on the first insulation layer 122 in such a way as to fill the first holes H1, the metal layer 132 is then etched back in such a way as to remain only on the bottoms of the first holes H1. The metal layer 132 is formed of a metal which has a work function of preferably 3.5˜5.5 eV. For example, the metal layer 132 is formed to contain at least one of Ag, Al, Au, Cr, Ni, Pt, Ti and W. One variation is that the metal layer 132 can be composed of a single layer formed of any one selected among Ag, Al, Au, Cr, Ni, Pt, Ti and W or an alloy layer containing at least one of them. After depositing a P+ polysilicon layer 134 on the first insulation layer 122 in such a way as to fill the first holes H1 having the metal layer 132 remaining on the bottoms thereof, the P+ polysilicon layer 134 is removed through a CMP (chemical mechanical polishing) process until the first insulation layer 122 is exposed. Thereupon, the P+ polysilicon layer 134 having undergone the CMP process is etched back such that the P+ polysilicon layer 134 is recessed. Through this, Schottky diodes 130 composed of the metal layer 132 and the P+ polysilicon layer 134 are formed in the first holes H1 as switching elements.

Referring to FIG. 2C, an ohmic contact layer 136 is formed on the recessed P+ polysilicon layer 134 and the first insulation layer 122 to ensure ohmic contact between the P+ polysilicon layer 134 of the Schottky diodes 130 and a phase change layer which will be subsequently formed. The ohmic contact layer 136 may comprise, for example, a metal silicide layer.

Referring to FIG. 2D, the ohmic contact layer 136 is removed through a CMP process or an etch-back process until the first insulation layer 122 is exposed. As a consequence, the ohmic contact layer 136 remains only on the recessed P+ polysilicon layer 134, that is, in the first holes H1.

Referring to FIG. 2E, after forming a second insulation layer 140 on the Schottky diodes 130 including the ohmic contact layer 136 and on the first insulation layer 122, by etching the second insulation layer 140, a plurality of second holes H2 are defined in such a way as to expose the ohmic contact layer 136 of the Schottky diodes 130. Then, after depositing a conductive layer for bottom electrodes on the surfaces of the second holes H2 and the second insulation layer 140, by etching back the conductive layer, bottom electrodes 142 are formed in the form of spacers on the sidewalls of the second holes H2. The reason why the bottom electrodes 142 are formed in the form of spacers on the sidewalls of the second holes H2 is to reduce the contact area between the bottom electrode 142 and the phase change layer which will be subsequently formed so that driving current can be decreased.

Next, after depositing a third insulation layer 144 on the second insulation layer 140 in such a way as to fill the second holes H2 which have the bottom electrodes 142 formed on the sidewalls thereof, the third insulation layer 144 is CMPed (chemically and mechanically polished) until the second insulation layer 140 is exposed.

Referring to FIG. 2F, a phase change material layer and a conductive layer for top electrodes are sequentially formed on the bottom electrodes 142, the third insulation layer 144 and the second insulation layer 140. Thereafter, by etching the conductive layer for top electrodes and the phase change material layer, stack patterns of a phase change layer 150 and a top electrode 160 are formed. Preferably, the stack patterns of the phase change layer 150 and the top electrode 160 are formed in the type of lines which extend in a direction perpendicular to the extending direction of the bit line 120. The bottom electrodes 142 contact only portions of the phase change layer 150. That is to say, the contact area between the bottom electrode 142 and the phase change layer 150 is decreased due to the presence of the third insulation layer 144 serving as spacers. Thus, the contact area between the bottom electrode 142 and the phase change layer 150 can be adjusted by changing the width of the third insulation layer 144 serving as spacers.

Thereafter, while not shown in the drawings, by sequentially conducting a series of well-known subsequent processes, the manufacture of the phase change memory device in accordance with the first embodiment of the present invention is completed.

While the P+ polysilicon layer 134 is adopted in the first embodiment of the present invention to constitute the Schottky diodes 130, it is conceivable that an N+ polysilicon layer can be adopted in place of the P+ polysilicon layer 134. After depositing and CMPing (chemically and mechanically polishing) the N+ polysilicon layer, in the same manner after depositing and CMPing the P+ polysilicon layer 134, the N+ polysilicon layer is recessed by being etched back, and a metal suicide is formed on the recessed N+ polysilicon layer as an ohmic contact layer.

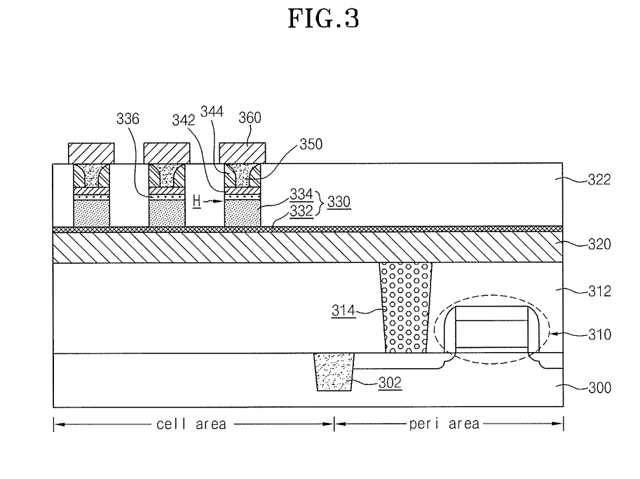

FIG. 3 is a sectional view illustrating a phase change memory device in accordance with a second embodiment of the present invention.

Referring to FIG. 3, an isolation structure 302 is formed in the surface of a semiconductor substrate 300 that has a cell area and a peripheral area, in such a way as to delimit active regions in each of the cell area and the peripheral area. A driving element 310 such as a transistor including a gate and junction regions is formed in the active region of the peripheral area of the semiconductor substrate 300. An interlayer dielectric 312 is formed on the overall surface of the semiconductor substrate 300 including the peripheral area that is formed with the driving element 310. A bit line 320 is formed on the interlayer dielectric 312 to be electrically connected with a portion of the driving element 310 via a plug 314 which is formed in the interlayer dielectric 312. The plug 314 is formed of, for example, tungsten, and includes a barrier layer (not shown) that is formed on the interfaces of the plug 314 with the interlayer dielectric 312 and the driving element 310. Spacers (not shown) comprising a nitride layer are formed on both sidewalls of the bit line 320.

A metal layer 332 is formed on the bit line 320. The metal layer 332 serves as a component element of the Schottky diodes. The metal layer 332 is formed of a metal which preferably has a work function of 3.5˜5.5 eV. For example, the metal layer 332 may be composed of a single layer formed of any one selected among Ag, Al, Au, Cr, Ni, Pt, Ti and W or an alloy layer containing at least one of them. Here, it can be understood that spacers comprising a nitride layer are also formed on both sidewalls of the metal layer 332.

An insulation layer 322 is formed on the interlayer dielectric 312 including the metal layer 332. Holes H1 are defined in the insulation layer 322 in correspondence to respective cells in such a way as to expose portions of the metal layer 332. An N+ polysilicon layer 334 is formed on the bottoms of the holes H in a manner such that the N+ polysilicon layer 334 cooperates with the portions of the metal layer 332 exposed through the holes H1 to constitute Schottky diodes 330. After the N+ polysilicon layer 334 is deposited to fill the holes H, it is etched back to remain to a thickness that does not completely fill the holes H. Each Schottky diode 330 may be composed of the stack structure of the metal layer 332 that is formed on the overall surface of the bit line 320 and the N+ polysilicon layer 334 may be formed on the portions of the metal layer 332 in a dot type pattern configuration. An ohmic contact layer 336 comprising, preferably, a metal silicide, is formed on the N+ polysilicon layer 334 of the Schottky diodes 330.

Meanwhile, it is envisioned that the Schottky diode 330 can also be formed by the stack structure of the metal layer 332 and a P+ polysilicon layer in place of the stack structure of the metal layer 332 and the N+ polysilicon layer 334.

In succession, bottom electrodes 342 are formed on the ohmic contact layer 336 in the holes H to a thickness that does not completely fill the holes H. Insulation layer spacers 344 are formed on the sidewalls of the holes H at both side ends of the bottom electrodes 342. A phase change layer 350 is formed on the bottom electrodes 342 between the insulation layer spacers 344 in such a way as to completely fill the holes H. The insulation layer spacers 344 play a role of decreasing the size of an area in which the phase change layer 350 is to be formed, that is, of decreasing the contact area between the phase change layer 350 and the bottom electrodes 342 and thereby reducing reset current. The insulation layer spacers 344 comprise, for example, a nitride layer.

Top electrodes 360 are formed on the insulation layer 322 including the phase change layer 350 and the insulation layer spacers 344. The top electrodes 360 are formed in the type of lines that extend in a direction substantially perpendicular to the bit line 320.

In the above-described phase change memory device in accordance with the second embodiment of the present invention, in the case that the Schottky diode 330 is composed of the stack structure of the metal layer 332 and the N+ polysilicon layer 334, current flows from the top electrode 360 to the bit line 320. Conversely, in the case that the Schottky diode 330 is composed of the metal layer 332 and the P+ polysilicon layer, current flows from the bit line 320 to the top electrode 360.

Accordingly, similar to the aforementioned embodiment, since the phase change memory device in accordance with the second embodiment of the present invention has a configuration in which Schottky diodes as switching elements are placed on a bit line formed of a metallic material, it is possible to prevent or at least minimize a voltage drop phenomenon from occurring and deterioration of current drivability brought about by a relatively high resistance. Therefore, the present invention does not need to form a strap metal, and thus advantages can be provided in terms of a design and processes of the present invention.

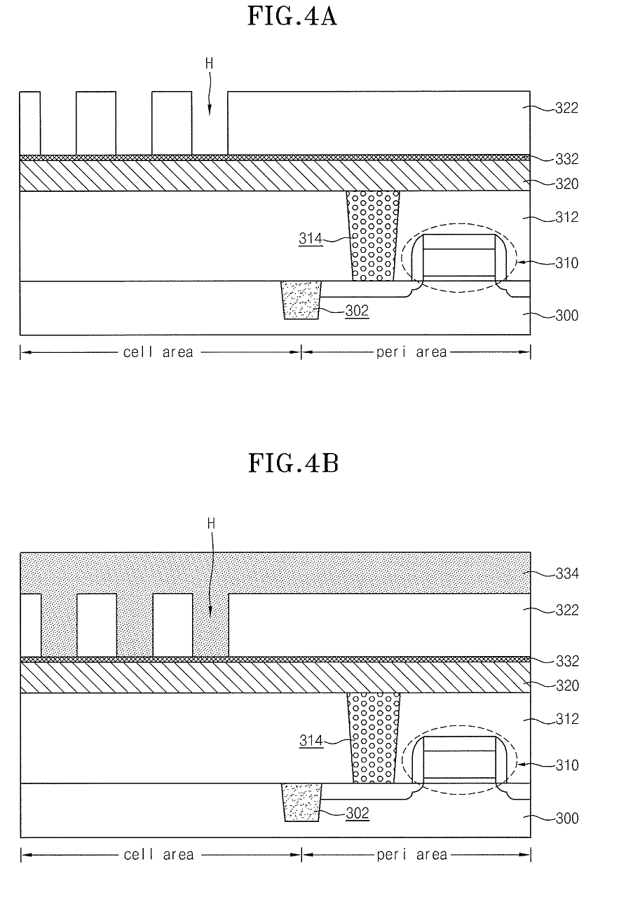

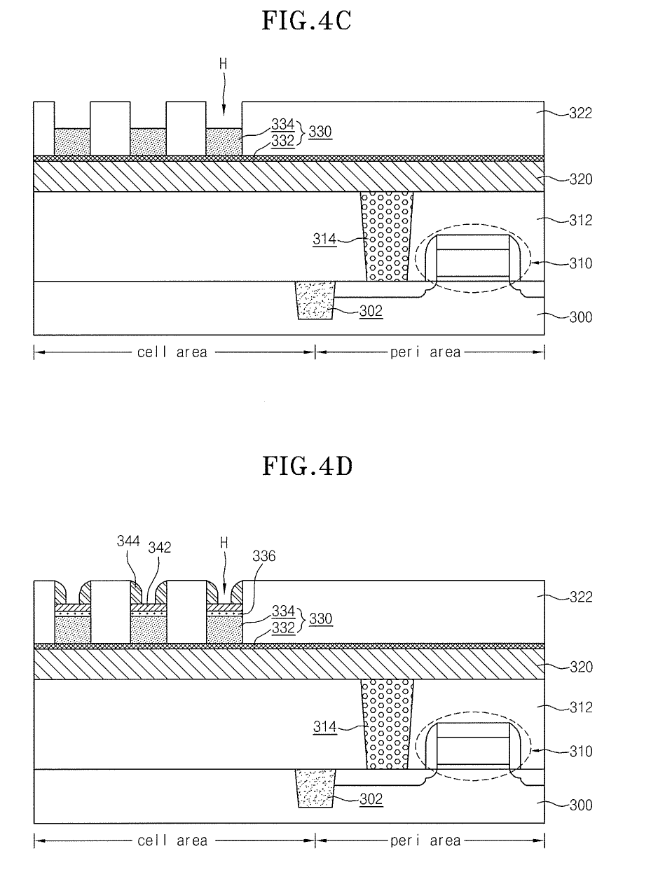

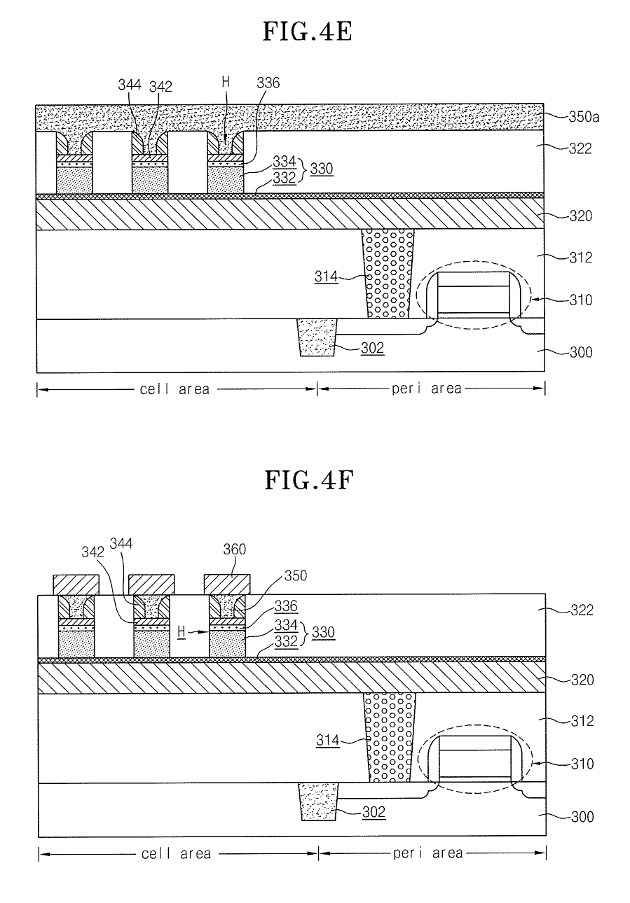

FIGS. 4A through 4F are sectional views illustrating the processes of a method for manufacturing the phase change memory device in accordance with the second embodiment of the present invention. The method will be described below.

Referring to FIG. 4A, an isolation structure 302 is formed in the surface of a semiconductor substrate 300 that has a cell area and a peripheral area, in such a way as to delimit active regions in the cell area and the peripheral area. A driving element 310 comprising a transistor including a gate and junction regions is formed in the active region of the peripheral area of the semiconductor substrate 300. An interlayer dielectric 312 is formed on the overall surface of the semiconductor substrate 300 including the peripheral area in which the driving element 310 is formed. After defining a contact hole by etching the interlayer dielectric 312 in such a way as to expose a portion of the driving element 310 that is formed in the peripheral area, a plug 314 is formed by filling a conductive layer, for example, a tungsten layer, in the contact hole. It is preferred that, before filling the tungsten layer, a barrier layer be formed in advance on the surface of the contact hole.

A conductive layer for bit lines, that is made of a metal, is deposited on the interlayer dielectric 312 including the plug 314. A metal layer 332 for Schottky diodes is deposited on the conductive layer for bit lines. The metal layer 332 for Schottky diodes may be formed of a metal which has a work function of 3.5˜5.5 eV. For example, the metal layer 332 for Schottky diodes is composed of a single layer formed of any one selected among Ag, Al, Au, Cr, Ni, Pt, Ti and W or an alloy layer containing at least one of them.

While not shown in detail, by etching the metal layer 332 and the conductive layer for bit lines, a bit line 320 is formed to extend in one direction, for example, the X-axis direction, and the metal layer 332 remains only on the bit line 320. Spacers (not shown) comprising, for example, a nitride layer are formed on both sidewalls of the remaining metal layer 332 and the bit line 320 which extend in the X-axis direction.

After forming an insulation layer 322 on the interlayer dielectric 312 including the remaining metal layer 332 and the bit line 320, by etching the insulation layer 322, a plurality of holes H are defined in such a way as to expose portions of the metal layer 332. It can be understood that the holes H are defined in correspondence to respective cells.

Referring to FIG. 4B, an N+ polysilicon layer 334 is deposited on the insulation layer 322 to substantially completely fill the holes H. The N+ polysilicon layer 334 is a component element of the Schottky diodes in cooperation with the portions of the metal layer 332 exposed through the holes H.

Meanwhile, in order to make the Schottky diodes, a P+ polysilicon layer can be deposited in place of the N+ polysilicon layer 334.

Referring to FIG. 4C, after CMPing the N+ polysilicon layer 334, the N+ polysilicon layer 334 is etched back such that the N+ polysilicon layer 334 remains in a dot type configuration only on the bottoms of the holes H. Through this, Schottky diodes 330 are formed such that each of them has the stack structure of the portion of the metal layer 332 which is exposed through the hole H and the N+ polysilicon layer 334 which remains on the portion of the metal layer 332 in the dot type configuration.

Referring to FIG. 4D, an ohmic contact layer 336 comprising, for example, a metal silicide is formed on the surface of the N+ polysilicon layer 334 in the holes H. After depositing a conductive layer for bottom electrodes on the insulation layer 322 in such a way as to fill the holes H in which the ohmic contact layer 336 is formed, by etching back the conductive layer for bottom electrodes, bottom electrodes 342 are formed. The bottom electrodes 342 are formed to a thickness that does not completely fill the holes H.

After depositing an insulation layer, for example, a nitride layer, to a uniform thickness on the surfaces of the holes H in which the bottom electrodes 342 are formed and on the insulation layer 322, by etching back the nitride layer, insulation layer spacers 344 are formed on the sidewalls of the holes H at both side ends of the bottom electrodes 342. The insulation layer spacers 344 are formed in order to decrease or limit the contact area between the bottom electrodes 342 and a phase change layer that will be subsequently formed. Therefore, depending upon with the deposition width of the nitride layer, the contact area between the bottom electrodes 342 and the phase change layer can be adjusted.

Referring to FIG. 4E, a phase change material layer 350a is deposited on the insulation layer 322 to completely fill the holes H in which the insulation layer spacers 344 are formed. The deposition of the phase change material layer 350a is implemented through PVD (physical vapor deposition) such as sputtering or CVD (chemical vapor deposition).

Referring to FIG. 4F, the phase change material layer 350a is CMPed until the insulation layer 322 is exposed, and through this, a phase change layer 350 is formed on the bottom electrodes 342 between the insulation layer spacers 344 to fill the holes H. Since the contact area between the phase change layer 350 and the bottom electrode 342 is decreased by the presence of the insulation layer spacers 344, reset current for changing the phase of the phase change layer 350 can be reduced.

After depositing a conductive layer for top electrodes on the insulation layer 322 including the phase change layer 350 and the insulation layer spacers 344, by etching the conductive layer for top electrodes, top electrodes 360 are formed. The top electrodes 360 are formed in the type of lines which extend in a direction substantially perpendicular to the extending direction of the bit line 320.

Thereafter, while not shown in the drawings, by sequentially conducting a series of well-known subsequent processes, the manufacture of the phase change memory device in accordance with the second embodiment of the present invention is completed.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A phase change memory device comprising:
a semiconductor substrate having a cell area and a peripheral area;
a bit line on the semiconductor substrate;
switching elements on portions of the bit line in the cell area;
bottom electrodes on the switching elements;
a phase change layer on the bottom electrodes; and
top electrodes on the phase change layer.

2. The phase change memory device according to claim 1, further comprising a driving element in the peripheral area of the semiconductor substrate.

3. The phase change memory device according to claim 1, wherein the switching elements comprise Schottky diodes.

4. The phase change memory device according to claim 3, wherein the Schottky diodes comprise a P+ polysilicon layer stacked on a metal layer.

5. The phase change memory device according to claim 4, wherein the metal layer has a work function of 3.5˜5.5 eV.

6. The phase change memory device according to claim 5, wherein the metal layer contains at least one of Ag, Al, Au, Cr, Ni, Pt, Ti and W.

7. The phase change memory device according to claim 3, wherein the Schottky diodes comprise a N+ polysilicon layer stacked on a metal layer.

8. The phase change memory device according to claim 1, further comprising an ohmic contact layer interposed between the switching elements and the bottom electrodes.

9. The phase change memory device according to claim 8, wherein the ohmic contact layer comprises a metal silicide.

10. The phase change memory device according to claim 1, wherein the bottom electrodes directly contacts a portion of the phase change layer.

11. A phase change memory device comprising:
a semiconductor substrate having a cell area and a peripheral area;
an interlayer dielectric on the semiconductor substrate;
a bit line on the interlayer dielectric;
a first insulation layer on the interlayer dielectric including the bit line, the first insulation layer having a plurality of first holes that expose portions of the bit line;
Schottky diodes in the first holes used as switching elements;
a second insulation layer on the first insulation layer and on the Schottky diodes, the second insulation layer having a plurality of second holes that expose respective Schottky diodes;
bottom electrodes on sidewalls of the second holes;
a third insulation layer in the second holes and on the bottom electrodes on the sidewalls of respective second holes; and
a phase change layer and top electrodes stacked on the bottom electrodes, the third insulation layer and the second insulation layer.

12. The phase change memory device according to claim 11, further comprising a driving element in the peripheral area of the semiconductor substrate.

13. The phase change memory device according to claim 11, wherein the Schottky diodes comprises either a P+ polysilicon layer stacked on a metal layer or an N+ polysilicon layer stacked on the metal layer.

14. The phase change memory device according to claim 13, wherein the metal layer has a work function of 3.5˜5.5 eV.

15. The phase change memory device according to claim 14, wherein the metal layer contains at least one of Ag, Al, Au, Cr, Ni, Pt, Ti and W.

16. The phase change memory device according to claim 13, wherein the Schottky diodes are recessed into the first holes.

17. The phase change memory device according to claim 11, further comprising an ohmic contact layer interposed between the Schottky diodes and the bottom electrodes.

18. The phase change memory device according to claim 17, wherein the ohmic contact layer comprises a metal silicide.

19. A phase change memory device comprising:
a semiconductor substrate having a cell area and a peripheral area;
a bit line on the semiconductor substrate;
switching elements on portions of the bit line in the cell area;
bottom electrodes on the switching elements;
insulation layer spacers on the bottom electrodes;
a phase change layer on the bottom electrodes and on the insulation layer spacers; and
top electrodes on the phase change layer.

20. The phase change memory device according to claim 19, further comprising a driving element in the peripheral area of the semiconductor substrate.

21. The phase change memory device according to claim 19, wherein the switching elements comprise Schottky diodes.

22. The phase change memory device according to claim 21, wherein each Schottky diode comprises either an N+ polysilicon layer stacked on a metal layer or a P+ polysilicon layer stacked on the metal layer in which the metal layer is on the bit line.

23. The phase change memory device according to claim 22, wherein the metal layer has a work function of 3.5˜5.5 eV.

24. The phase change memory device according to claim 23, wherein the metal layer contains at least one of Ag, Al, Au, Cr, Ni, Pt, Ti and W.

25. The phase change memory device according to claim 19, further comprising an ohmic contact layer interposed between the switching elements and the bottom electrodes.

26. The phase change memory device according to claim 25, wherein the ohmic contact layer comprises a metal silicide.

27. The phase change memory device according to claim 19, wherein the insulation layer spacers comprise a nitride layer.

28. A phase change memory device comprising:
a semiconductor substrate having a cell area and a peripheral area;
an interlayer dielectric on the semiconductor substrate;
a bit line on the interlayer dielectric;
a metal layer on the bit line;
an insulation layer on the interlayer dielectric and on the metal layer, the insulation layer having a plurality of holes that expose portions of the metal layer;
a polysilicon layer having anyone conductivity type, the polysilicon layer in the holes and contacting the exposed portions of the metal layer such that the polysilicon layer and the exposed portion of the metal layers constitute Schottky diodes used as switching elements;
bottom electrodes on the polysilicon layer;
insulation layer spacers on sidewalls of the holes and on the bottom electrodes;
a phase change layer on the bottom electrodes on the insulation layer spacers such that the phase change layer completely fills the holes; and
top electrodes formed on the insulation layer and on the phase change layer.

29. The phase change memory device according to claim 28, further comprising a driving element formed in the peripheral area of the semiconductor substrate.

30. The phase change memory device according to claim 29, wherein the polysilicon layer is either a N+ conductivity type or a P+ conductivity type.

31. The phase change memory device according to claim 30, wherein the metal layer has a work function of 3.5˜5.5 eV.

32. The phase change memory device according to claim 31, wherein the metal layer contains at least one of Ag, Al, Au, Cr, Ni, Pt, Ti and W.

33. The phase change memory device according to claim 28, further comprising an ohmic contact layer interposed between the polysilicon layer and the bottom electrodes.

34. The phase change memory device according to claim 33, wherein the ohmic contact layer comprises a metal silicide.

35. The phase change memory device according to claim 28, wherein the insulation layer spacers are composed of a nitride layer.

36. A method for manufacturing a phase change memory device, comprising the steps of:
forming a bit line on a semiconductor substrate that has a cell area and a peripheral area;
forming switching elements on portions of the bit line in the cell area;
forming bottom electrodes on the switching elements; and
forming stack patterns of a phase change layer and a top electrode on the bottom electrodes.

37. The method according to claim 36, wherein, before the step of forming the bit line, the method further comprises the step of:
forming a driving element in the peripheral area of the semiconductor substrate.

38. The method according to claim 36, wherein the switching elements comprise Schottky diodes.

39. The method according to claim 38, wherein the Schottky diodes comprise a P+ polysilicon layer stacked on a metal layer.

40. The method according to claim 39, wherein the metal layer has a work function of 3.5˜5.5 eV.

41. The method according to claim 40, wherein the metal layer contains at least one of Ag, Al, Au, Cr, Ni, Pt, Ti and W.

42. The method according to claim 39, wherein the Schottky diodes comprise an N+ polysilicon layer stacked on a metal layer.

43. The method according to claim 36, wherein, after the step of forming the switching elements and before the step of forming the bottom electrodes, the method further comprises the step of forming an ohmic contact layer on surfaces of the switching elements.

44. The method according to claim 43, wherein the ohmic contact layer comprises a metal silicide.

45. The method according to claim 36, wherein the bottom electrodes are formed to directly contact a portion of the phase change layer.

46. A method for manufacturing a phase change memory device, comprising the steps of:
forming an interlayer dielectric on a semiconductor substrate that has a cell area and a peripheral area;
forming a bit line on the interlayer dielectric;
forming a first insulation layer on the interlayer dielectric and on the bit line, the first insulation layer comprising a plurality of first holes that expose portions of the bit line;
forming Schottky diodes in the respective first holes for use as switching elements;
forming a second insulation layer on the first insulation layer and on the Schottky diodes, the second insulation layer comprising a plurality of second holes that expose the portions of the Schottky diodes;
forming bottom electrodes on sidewalls of the second holes;
forming a third insulation layer to completely fill the second holes that have the bottom electrodes formed on the sidewalls thereof; and
forming stack patterns of a phase change layer and a top electrode on the bottom electrodes, the third insulation layer and the second insulation layer.

47. The method according to claim 46, wherein, before the step of forming the interlayer dielectric, the method further comprises the step of forming a driving element in the peripheral area of the semiconductor substrate.

48. The method according to claim 46, wherein the step of forming the Schottky diodes comprises the steps of:
forming a metal layer on bottoms of the first holes; and
forming a P+ polysilicon layer or an N+ polysilicon layer on the metal layer in the first holes.

49. The method according to claim 48, wherein the metal layer has a work function of 3.5˜5.5 eV.

50. The method according to claim 49, wherein the metal layer contains at least one of Ag, Al, Au, Cr, Ni, Pt, Ti and W.

51. The method according to claim 48, wherein, after the step of forming the P+ polysilicon layer or the N+ polysilicon layer, the method further comprises the steps of:
recessing the P+ polysilicon layer or the N+ polysilicon layer; and
forming an ohmic contact layer on a surface of the recessed P+ polysilicon layer or the recessed N+ polysilicon layer.

52. The method according to claim 51, wherein the ohmic contact layer comprises a metal silicide.

53. A method for manufacturing a phase change memory device, comprising the steps of:
forming a bit line on a semiconductor substrate that has a cell area and a peripheral area;
forming switching elements on portions of the bit line in the cell area;
forming bottom electrodes on the switching elements;
forming insulation layer spacers on both side ends of the switching elements;
forming a phase change layer on the bottom electrodes between the insulation layer spacers; and
forming top electrodes on the phase change layer.

54. The method according to claim 53, wherein before the step of forming the bit line, the method further comprises the step of forming a driving element in the peripheral area of the semiconductor substrate.

55. The method according to claim 53, wherein the switching elements comprise Schottky diodes.

56. The method according to claim 55, wherein the Schottky diodes have a stack structure of a metal layer and an N+ polysilicon layer or a stack structure of a metal layer and a P+ polysilicon layer.

57. The method according to claim 56, wherein the metal layer is formed on an overall surface of the bit line, and the N+ polysilicon layer or the P+ polysilicon layer is formed on portions of the metal layer.

58. The method according to claim 56, wherein the metal layer has a work function of 3.5˜5.5 eV.

59. The method according to claim 58, wherein the metal layer contains at least one of Ag, Al, Au, Cr, Ni, Pt, Ti and W.

60. The method according to claim 53, wherein after the step of forming the switching elements and before the step of forming the bottom electrodes, the method further comprises the step of forming an ohmic contact layer on surfaces of the switching elements.

61. The method according to claim 60, wherein the ohmic contact layer comprises a metal silicide.

62. The method according to claim 53, wherein the insulation layer spacers comprise a nitride layer.

63. A method for manufacturing a phase change memory device, comprising the steps of:
forming an interlayer dielectric on a semiconductor substrate that has a cell area and a peripheral area;
forming a bit line on the interlayer dielectric;
forming a metal layer on an overall surface of the bit line;
forming an insulation layer on the interlayer dielectric including the metal layer, the insulation layer having a plurality of holes that expose portions of the metal layer;
forming a polysilicon layer on bottoms of the respective holes, the polysilicon layer comprising a plurality of Schottky diodes that act as switching elements in cooperation with the portions of the metal layer, wherein the Schottky diodes are exposed through the holes and have any one conductivity type;
forming bottom electrodes on the polysilicon layer in the holes;
forming insulation layer spacers on sidewalls of the holes of the bottom electrodes;
forming a phase change layer on the bottom electrodes between the insulation layer spacers to completely fill the holes; and
forming top electrodes on the insulation layer and on the phase change layer.

64. The method according to claim 63, wherein before the step of forming the interlayer dielectric, the method further comprises the step of forming a driving element in the peripheral area of the semiconductor substrate.

65. The method according to claim 63, wherein the polysilicon layer is stacked directly on top of the metal layer to form the Schottky diodes.

66. The method according to claim 65, wherein the metal layer has a work function of 3.5˜5.5 eV.

67. The method according to claim 66, wherein the metal layer contains at least one of Ag, Al, Au, Cr, Ni, Pt, Ti and W.

68. The method according to claim 63, wherein after the step of forming the polysilicon layer and before the step of forming the bottom electrodes, the method further comprises the step of forming an ohmic contact layer on the polysilicon layer.

69. The method according to claim 68, wherein the ohmic contact layer comprises a metal silicide.

70. The method according to claim 63, wherein the insulation layer spacers comprise a nitride layer.
